(19) United States
(12) Patent Application Publication
(10) Pub. No.: US 2017/0194961 A1
(43) Pub. Date: Jul. 6, 2017

(54) SWITCH FILM

(71) Applicants: Nanyang Technological University, Singapore (SG); Advanced Electroacoustic Pte Ltd, Singapore (SG)

(72) Inventors: Joseph Sylvester CHANG, Singapore (SG); Tong GE, Singapore (SG); Chai Lung LEE, Singapore (SG)

(21) Appl. No.: 15/314,501

(22) PCT Filed: May 29, 2015
(86) PCT No.: PCT/SG2015/050131

§ 371 Date: Nov. 28, 2016

(30) Foreign Application Priority Data
May 29, 2014 (SG) 10201402743R

(51) Int. Cl. H03K 17/96; H01L 41/08; A61J 1/03; H01L 41/297; H05K 1/16; H01H 3/12; H01L 41/083; H01L 41/293

(52) U.S. Cl. CPC H03K 17/962; H01L 41/083; H01L 41/0815; H01L 41/293; H01L 41/297; H05K 1/16; H01H 3/12; A61J 1/035; H05K 2201/10053; H05K 2201/10098

(57) ABSTRACT

A switch film comprising: a flexible film substrate; a switch supported by the flexible film substrate, the switch having a state consisting of one of: normally-open and normally closed, the switch configured to change its state upon application of at least a predetermined force; and an electronic circuit supported by the flexible film substrate and connected to the switch and configured to wirelessly transmit a signal upon change of state of the switch.

### FIELD OF THE INVENTION

This invention relates to a switch film, and to a pharmaceutical blister package comprising the switch film.

### BACKGROUND OF THE INVENTION

A pharmaceutical blister package typically comprises a plurality of discrete pockets or cavities integrally formed from a sheet of plastic that are sealed with a sheet of aluminium foil after a pill (i.e., a tablet or capsule containing a pharmaceutical preparation) has been placed in each pocket. This protects the individual pill from exposure to the environment until it is to be consumed, at which time the aluminium foil covering the pocket containing the tablet or capsule to be consumed is broken by the user to allow the pill to be removed from the blister package.

Smart packages [1, 2] have been devised that include an electronic circuit that is connected to a battery at all times and having a resistive sensor to monitor changes to the package, for example, to help users keep track of dosage times and quantities. Such smart packages are thus continuously powered, but lifespan of the battery is limited, therefore lifespan of these smart packages is also limited.

### SUMMARY OF INVENTION

The invention comprises a ‘switch film’ or switch film for use in blister packages for pharmaceutical pills. The switch film is configured to be provided on a standard pharmaceutical blister package without any need to modify the standard packaging process, thereby transforming or augmenting a standard passive/dummy package to embody intelligence—a ‘smart package’.

The switch film comprises a switch that can be either normally-open or normally-closed so that a change of state of the switch triggers the transmission of a signal to a smart device. In the case of a normally-open switch, it will change its state to be temporarily or permanently closed when the switch is sufficiently depressed, which may be beyond a predetermined force or when the substrate of the switch film is ruptured, depending on the desired application. For the normally-open switch, a circuit path within its associated electronics or electronic circuit is normally disconnected. When the switch has been sufficiently depressed to close the circuit, this change from an open switch connection (open-circuit) to a closed switch (short-circuit) connection provides information on the instance/time of access to a packaged item in a blister package on which the switch film is provided, for example, a pill in a pharmaceutical blister package. In the associated electronic circuit, the switch constitutes part of its conducting path. The associated electronic circuit may be passive, for example a passive Radio Frequency Identification (RFID) where the switch completes the circuit for its ensuing functionality, or it may be active, for example an active RFID or wireless transmitting circuit where the switch connects the associated electronic circuit to a battery cell.

One of the embodiments of the invention includes a normally-open switch, an associated electronic circuit, and one or more sensors. Each sensor serves to measure an environmental parameter, e.g. temperature, humidity, etc., and this parameter provides an indication of the quality of the packaged item (e.g. a pill in a pharmaceutical blister package).

The switch film has many applications, not just directed to packaging but also as a smart device, for example, as a smart Internet-of-Everything bandage.

As the switch film is thin and flexible, it may be applied to an existing packaging without modifying the existing packaging process; hence facilitating its applicability and associated low cost of usage.

According to a first aspect, there is provided a switch film comprising: a flexible film substrate; a switch supported by the flexible film substrate, the switch having a state consisting of one of: normally-open and normally closed, the switch configured to change its state upon application of at least a predetermined force; and an electronic circuit supported by the flexible film substrate and connected to the switch and configured to wirelessly transmit a signal upon change of state of the switch.

The switch film may comprise a plurality of switches supported by the flexible film substrate and the electronic circuit is configured to wirelessly transmit a distinct signal upon change of state of each of the plurality of switches.

The electronic circuit may be passive.

The electronic circuit may comprise a radio frequency transponder and the switch may be provided with a unique identification circuit.

The switch film may further comprise a battery provided to power the electronic circuit.

The switch film may comprise a plurality of electronic circuits each connected with a distinct one of the plurality of switches and configured to wirelessly transmit a distinct signal upon change of state of its connected switch.

The switch film may further comprise at least one sensor configured to sense an environmental parameter; and an indicator configured to provide an indication associated with data obtained by the at least one sensor upon change of state of the switch.

The switch film may further comprise a data logger configured to log data obtained from the at least one sensor.

The electronic circuit may be configured to transmit a signal comprising at least an indication of the data obtained by the at least one sensor upon change of state of the switch.

The switch may be a mechanically normally-open switch and the electronic circuit may include a transistor connected in parallel with the switch and a latch circuit configured to turn the transistor on when the switch is closed.

The switch may be a normally open switch comprising a top electrode and a bottom electrode configured to come into contact with each other upon application of the force. A permanent contact may be formed between the top electrode and the bottom electrode upon application of the force.

Application of the at least a predetermined force may rupture the flexible film substrate.

According to a second aspect, there is provided pharmaceutical blister package comprising: a plurality of pockets integrally formed from a plastic sheet; each of the plurality of pockets containing therein a pill, a sheet of aluminium foil sealing each pill in each pocket; and the switch film of the first aspect, wherein the flexible film substrate is disposed over the sheet of aluminium foil outside the plurality of pockets and each of the plurality of switches is disposed at each respective pocket.

Each of the plurality of switches may be configured to change its state upon application of the at least a predetermined force during removal of a pill from its respective pocket.

The signal may include date and time of removal of the respective pill from the blister package.

The data obtained by the at least one sensor may be indicative of a condition of at least one pill in the pharmaceutical blister package.

### BRIEF DESCRIPTION OF FIGURES

In order that the invention may be fully understood and readily put into practical effect there shall now be described by way of non-limitative example only exemplary embodiments of the present invention, the description being with reference to the accompanying illustrative drawings.

FIG. 1(a) is a schematic illustration of a cross-sectional side view of the switch film on a pharmaceutical blister package.

FIG. 1(b) is a schematic illustration of a bottom view of a first embodiment of the switch film on the pharmaceutical blister package.

FIG. 1(c) is a circuit block diagram of the first embodiment of the switch film.

FIG. 1(d) is a schematic illustration of the associated electronic circuit of the first embodiment of the switch film.

FIG. 2(a) is a schematic illustration of a bottom view of a second embodiment of the switch film on a pharmaceutical blister package.

FIG. 2(b) is a circuit block diagram of the second embodiment of the switch film.

FIG. 2(c) is a schematic illustration of the associated electronic circuit of the second embodiment of the switch film. FIG. 3(a) is a schematic illustration of a bottom view of a third embodiment of the switch film on a pharmaceutical blister package.

FIG. 3(b) is a circuit block diagram of the third embodiment of the switch film.

FIG. 3(c) is a schematic illustration of a first embodiment of the associated electronic circuit of the third embodiment of the switch film.

FIG. 3(d) is a schematic illustration of a second embodiment of the associated electronic circuit of the third embodiment of the switch film.

FIG. 4(a) is a photograph of a first embodiment of the switch.

FIG. 4(b) is a photograph of a top electrode and a bottom electrode of the switch of FIG. 4(a).

FIG. 5(a) is a schematic illustration of a cross-sectional side view of the switch film on a pharmaceutical blister package showing components of a switch.

FIG. 5(b) is a schematic illustration of a bottom view of the switch of FIG. 5(a).

FIG. 5(c) is a schematic illustration of the package of FIG. 5(a) during removal of a pill.

FIG. 6 is a schematic illustration of an embodiment of an electronic circuit having a latch circuit.

### DETAILED DESCRIPTION

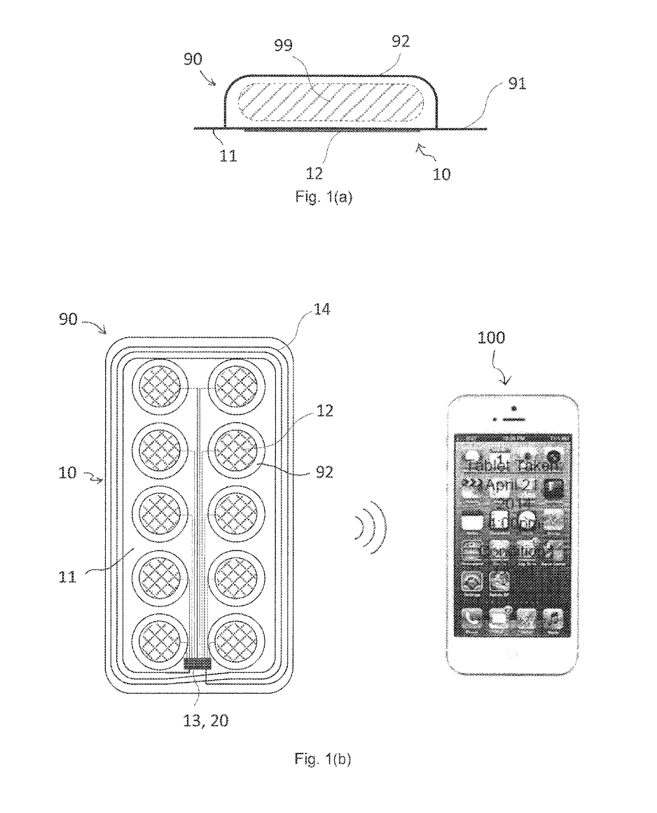

Exemplary embodiments of the switch film 10 and its various applications will be described below with reference to FIGS. 1 to 6, in which the same reference numerals are used to denote the same or similar parts.

In a first exemplary embodiment of the switch film 10, as shown in FIGS. 1(a) and (b), the switch film 10 comprises a film substrate 11, a number of switches 12, one or more batteries 13, an electronic circuit 20 and an antenna 14. The switch film 10 is configured to have a size that is the same or smaller than a blister package 90 on which the switch film 10 is disposed. The switches 12 are located adjacent where the package 90 is to be ruptured, that is, the switch film 10 is disposed on the blister package 90 on the sealing aluminium foil 91 outside the blister package 90, and configured such that each pocket 92 of the blister package 90 is provided with a switch 12. In FIG. 1(a) where the blister package 90 is shown oriented with the aluminium foil 92 below the pockets 91, each switch 12 is placed below a pill 99 contained in the pocket 92 and below the aluminium foil 91. The number of switches 12 or batteries 13 may be equal to the number of pills 99 in the package 90. The battery or batteries 13 used may be a regular pill-size battery or comprise LEES-SMART (Low Energy Electronic circuit Systems—Singapore MIT Alliance for Research and Technology) integrated micro-batteries comprising an array of micro-batteries, or an ultra-small battery cell.

An exemplary circuit block diagram and the schematic of the associated electronic circuit of the first embodiment of the switch film 10 is depicted in FIG. 1(c) and (d). For each pocket 91 and pill 99, as shown in FIG. 1(c), a dedicated circuit 40 including a switch 12, a battery 13 and an electronic circuit 20 is provided. The antenna 14 is configured to be shared by all dedicated circuits 40 for all the pills 99. The associated electronic circuit 20 for each dedicated circuit 40 for all the pills 99 can be integrated into an IC (integrated circuit) and the batteries 13 can either be separate or integrated on the same IC. The antenna 14 can either be printed on or realized within the switch film 10 using very thin printed conductors on the film substrate [3]. The normally-open switch 12 is connected between the battery 13 and the electronic circuit 20. In this embodiment, the switch 12 will become closed and remain closed when the switch 12 is sufficiently depressed so that both the aluminium foil 91 and the switch film 10 are ruptured. Alternatively, the switch film 10 can be configured to allow the switch 12 to be only temporarily closed to trigger the electronic circuit 20 accordingly, as will be discussed in greater detail below.

Because the switch 12 in the first exemplary embodiment is normally open, the electronic circuit 20 is normally disconnected from the battery 13, unlike prior-art smart packages [1, 2] that have circuits connected to the battery all the time (i.e. continuously). The normally-open (disconnection) connection between the electronic circuit 20 and the battery 13 means that the battery 13 remains normally unused, so that the only power drain from the battery 13 is its natural discharge. This consequently results in significantly improved shelf-life of the switch film 10 for a given battery 13 or significantly reduces the size of the battery 13 for the same shelf-life.

Once the package 90 at one of the pockets 92 has been ruptured to gain access to a pill 99, the switch 12 at that pocket 92 is closed and preferably remains closed, either mechanically or electronically as will be discussed in greater detail below. When this occurs, the electronic circuit 20 is then connected to the battery 13 and commences to transmit a signal for a predetermined time or until the battery 13 is exhausted. On one embodiment, the signal may be transmitted to a smart device 100 such as a smart phone; alternatively the signal may be transmitted to a receiving device such as a wifi transceiver, for example.

In an alternative embodiment to the switch remaining closed, the switch may alternatively be closed only temporarily, as will be described in greater detail below.

The electronic circuit 20 can be very simple. In an exemplary embodiment as shown FIG. 1 (d), the electronic circuit 20 comprises a digital circuit 18 that stores an ID number of each pill 99, a mixer 22, a clock or carrier generator 23 and a power amplifier 24. All these blocks 18, 21, 22, 23, 24 are simple to realize and consume very low power. The digital circuit 18 that stores the ID number can be realized by providing several flip-flops and combinational logic circuits; an alternative is a ROM (read-only-memory). The mixer 22 can be realized using an NAND gate. The clock generator 23 can be realized using a relaxation oscillator. The transmitter can be realized using an inverter.

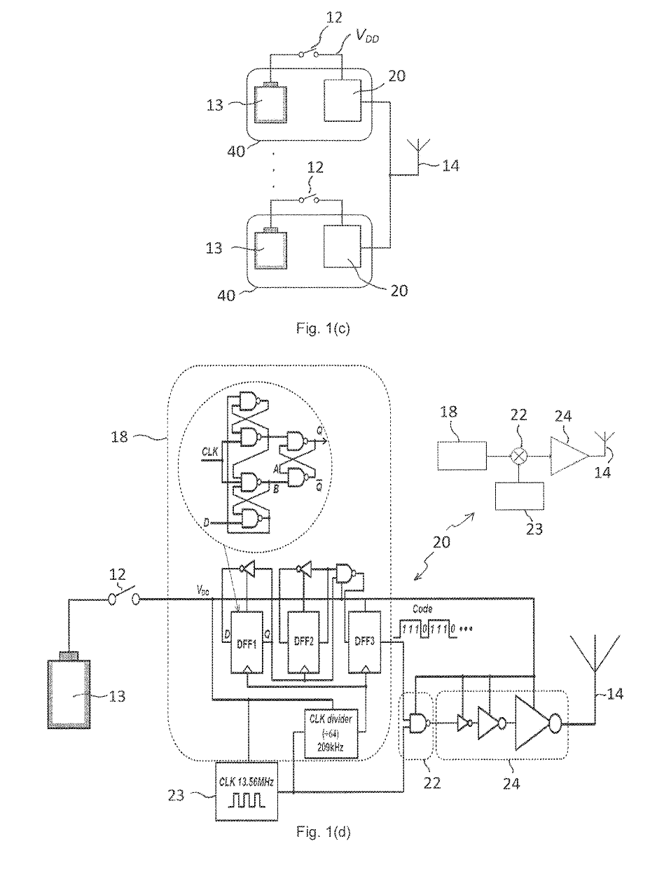

In a second exemplary embodiment of the switch film 10, as shown in FIGS. 2(a) to (c), the switch film 10 further includes a sensor 15, a data logger 16, an additional battery 33 (resulting in a total of n+1 batteries, where n is the number of pills 99 or pockets 92 in the blister package 90) and an indicator 17. In the second exemplary embodiment, the sensor 12 and the data logger 16 are continuously connected to the additional battery 33 that is shared by the sensor 12 and the data logger 16, whilst the electronic circuit 20 provided for each pill 99 is configured to connected to its respective battery 13 only when its associated switch 12 is closed.

The sensor 15 is configured to sense an environmental parameter (e.g., temperature, humidity, etc.), and may be configured to sense the condition of the package 90 periodically (e.g., every 4 hours). Sensed data or data obtained by the sensor 15 is logged into the data logger 16. The data logger 16 is electronically connected to the electronic circuit 20 provided for each pill 99. The indicator 17 is configured to provide a user with an indication associated with data obtained by the sensor 15.

When a pill 99 is removed from its pocket 92 of the package 90, the switch 12 underneath the pill 99, i.e., on the aluminium foil 91 covering the pocket 92, is closed, and the electronic circuit 20 is connected to the battery 13 and energized. The pertinent electronic circuit 20 first reads the data from the data logger 16 and a signal processing circuit 25 of the electronic circuit 20 computes the condition of the pill 99. The condition of the pill 99 is then indicated by the indicator 17, which may for example be a display, or a multi-colored LED that lights up with a predetermined colour according to the condition of the pill 99 as sensed by the sensor 15, etc. The electronic circuit 20 also wirelessly transmits a signal to a smart device 100 to indicate the juncture of pill removal, and possibly the condition of the pill 99. The electronic circuit 20 may thus also be configured to transmit a signal comprising at least an indication of the data obtained by the sensor 15 upon change of state of the switch 12, that is, the signal may be indicative of the data or it may comprise the data itself.

Many variations may be made to the second embodiment. For example, in one variation, a user may wish only to ascertain the quality of the pill 99. In this case, the switch film 10 may be configured so that the user may depress the switch 12 until the switch 12 is closed for a certain time and the electronic circuit 20 will indicate the quality of the pill 99 via the indicator 17, but without rupturing the flexible film substrate 11 or aluminium foil 91 of the package 90 so that the pill 99 remains in the encapsulation and there is no wireless transmission of a signal.

In another variation, the switch film 10 may be configured to provide each pill 99 with two switches 12, one switch to indicate the condition of the pill 99 while another switch is designed to sense rupture of the film substrate 11 when the pill 99 is extracted.

In yet another variation, an individual switch 12 may be provided for each pill 99, and the blister package 90 may have a shared switch 32 to indicate the quality of the pills 99.

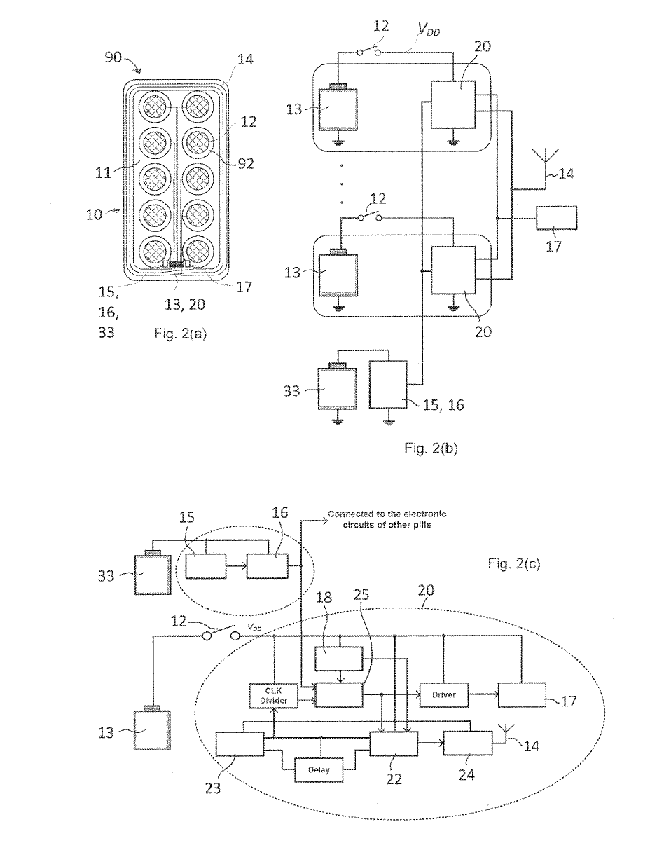

In a third exemplary embodiment of the switch film 10, as shown in FIGS. 3(a) to (d), the electronic circuits 20 are essentially a passive RFID tag and the smart device 100 (i.e. a smart phone) functions as a reader for the RFID tag. In this embodiment, all batteries may be eliminated. Since the electronic circuit 20 is completely passive, there is the potential for such a switch film 10 to be very low-cost. The information that indicates the change from the connection of a normally-open switch 12 to its closed-connection is the completion (short-circuit) of a circuit path, hence the functionality of the passive circuit; and the converse holds for a normally-closed switch. Without a battery, the power for the associated electronic circuit 20 is derived from the smart device 100. As can be seen in FIG. 3(b), the electronic circuit 20 comprises a RFID transponder circuit 20 that is shared by all the pills 99 in the package 90 and each pill 99 has a dedicated ID Number circuit 18. There are a number of methods to realize this function and two circuit examples are depicted in FIGS. 3(c) and 3(d).

The RFID transponder circuit 20 comprises a radio frequency (RF) transmission stage 51, a rectifier stage 52 and a digital modulation stage 53. The RF transmission stage 51 receives the RF power from the smart device 100 and the received power is converted to a direct current (DC) supply voltage by the rectifier stage 52. The DC supply voltage powers up the digital modulation stage 53 and the ID number blocks 18 that are connected by means of the pertinent switch(es) 12. The ID number blocks 18 output the ID number of the respective pill 99 connected to each switch 12. The ID number 18 modulates (turns on and off) a transistor in the digital modulation stage 53, hence modulating the RF transmission stage 51. The modulation of the RF transmission stage 51 results in a change in the electromagnetic field and the smart device 100 (RFID reader) detects the change of the electromagnetic field and recovers the ID number.

In a first exemplary circuit, as illustrated in FIG. 3(c), all the ID number blocks 18 are turned on but only the one associated with a pill 99 that is extracted from the package 90 will be connected to the digital modulation stage 53 when the normally-open switch underneath that pill 99 is closed during removal of the pill 99, thereby completing a conducting path between the ID number circuit 18 and the digital modulation stage 53.

In a second exemplary circuit illustrated in FIG. 3(d), all the ID number blocks 18 are connected to the digital modulation stage 53 of the RFID transponder 20 but only the ID number block 18 associated with pill 99 that is removed from the package 90 will be powered on when the normally-open switch 12 underneath that pill 99 is closed during removal of the pill 99 from the package 90, thereby completing a conducting path between the supply of the ID number circuit 18 and the rectifier Stage 52.

In a fourth exemplary embodiment of the switch film, the switch film of the third exemplary embodiment described above may be configured to further include a sensor, data logger, an indicator and a battery in the package, similar to those of the second embodiment shown in FIGS. 2(a) to (c), such that the switch film can sense and log the environmental condition during storage/transportation. In this design, the sensor and data logger are connected to the battery continuously and the indicator can be either powered by the battery or by the transmitted RF power from the smart device. This design is similar to the second exemplary embodiment except that communications between the switch film and the smart device 100 is via a passive RFID means like that of the third exemplary embodiment.

For all embodiments, the film substrate 11 is a flexible film substrate and may comprise a plastic or polymeric film, such as polycarbonate film. The electronic circuit 20 of the switch film 10 can be realized by conventional silicon processes and connected to the switch 12 by printed conductors within/on the flexible film substrate 11 [3]. The sensor(s) 15 described above in the second and fourth exemplary embodiments of the switch film can be printed using printed electronic circuit on the flexible film substrate 11.

Switch Designs

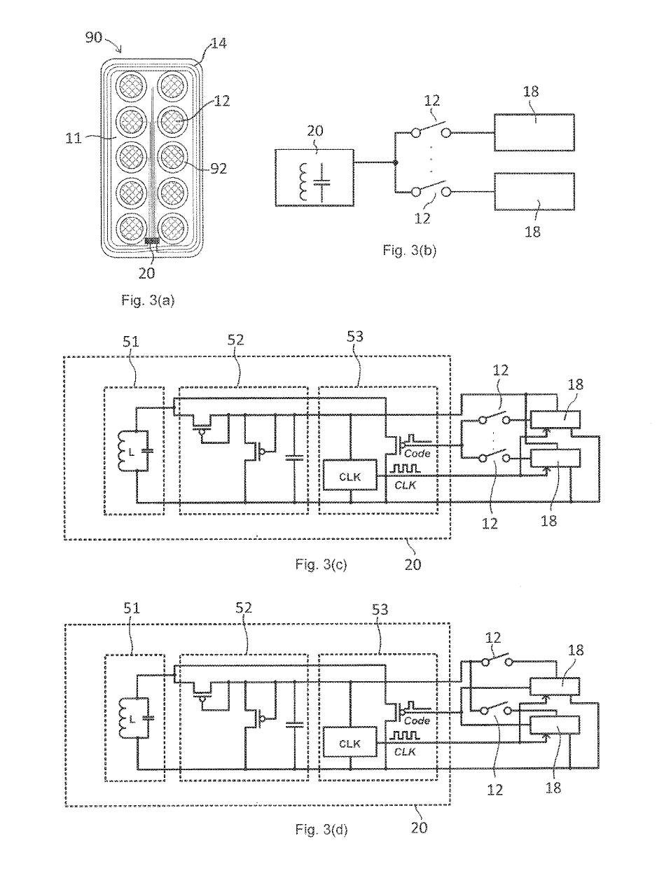

Several embodiments of the switch design are envisaged. In a first exemplary embodiment of the switch 12 as shown in FIGS. 4(a) and (b), the switch 12 is a normally-open momentary- on switch 12 having a top switch electrode 61 and bottom switch electrode 62. The top electrode 61 is a silver coated plastic film, and is hence electrically conductive. The bottom electrode 62 has a middle strip comprising a conductive silver-coated section 66 as a shown in FIG. 4(b) and two non-conductive dielectric-coated sections 67 (left and right sides) on each side of the middle strip 66. The switch 12 is normally-open when it is not depressed. When either the top or bottom electrode 61 or 62 is depressed, the conductive top electrode 61 surface makes contact with the conductive middle section 66 of the bottom electrode 62, and the top and bottom electrodes 61, 62 are short-circuit, i.e. momentarily-closed. When the pressure to depress the switch 12 is released, the switch 12 returns to its normally-open state.

A second exemplary embodiment where the switch 12 is normally-open and permanently-on after being depressed can be realized, for example, by coating the top 61, bottom 62 or both electrodes 61, 62 with a conductive adhesive, so that the electrodes 61, 62 will remain and stay shorted upon contact. The permanently-on state may therefore be realized mechanically; alternative the permanently-on state can be realized electronically, as will be described in greater detail below.

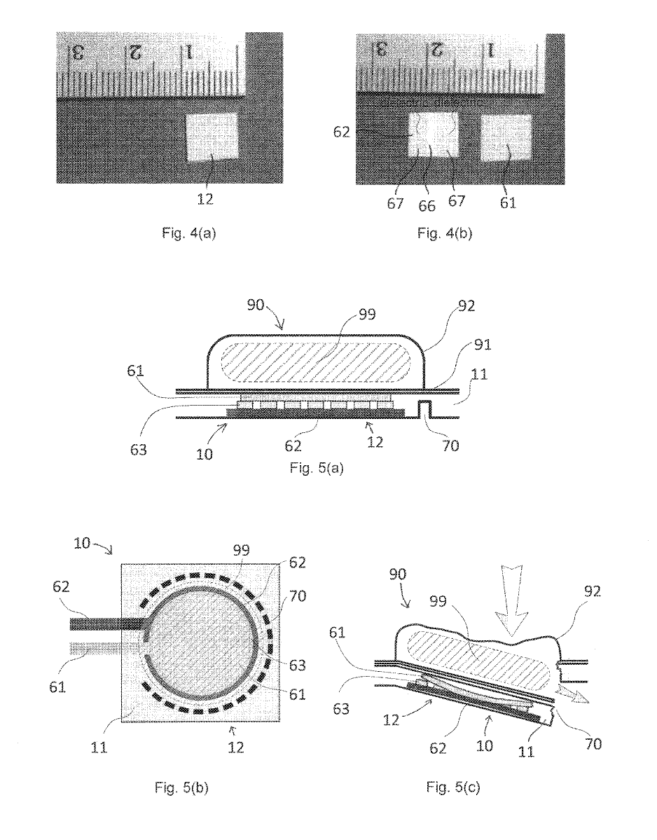

In a third exemplary embodiment of the switch 12 as shown in FIGS. 5(a) to (c), the switch 12 is normally-open and permanently-on after being depressed. As can be seen in FIG. 5(a), the switch film 10 is adhered to the aluminium foil 91 of the blister package 90. The normally-open switch 12, which embedded within the flexible film substrate 11, comprises a top switch electrode 61, a bottom switch electrode 62 and a dielectric layer 63 which separates the top 61 and bottom 62 electrodes. The switch 12 is encapsulated within the film substrate 11 such that the switch 12 is always encapsulated and never makes contact with the pill 99. The film substrate 11 is perforated 70 around each pocket 92 of the package 90 to facilitate rupture when a pill 99 is to be removed from the package 90. This is an important consideration in packaging of food and drugs to prevent contamination from any switch materials/chemicals.

When the pill 99 is extracted from its package 90 for ingestion, as depicted in FIG. 5(c), the aluminium foil 91 and the substrate 11 of the switch film 10 are ruptured along the perforation 70 of the switch film 10. Due to the pressure applied onto the pill 99 by pushing on its pocket 92 from the exterior of the package 90, the top and bottom electrodes 61, 62 of the switch 12 come into contact with each other. As transmission to the smart device 100 needs to be of some duration or continuous until the battery 13 is exhausted, the switch 12 should be closed for some duration or permanently after the pill 99 has been extracted from its encapsulation. As mentioned earlier, there are two ways to realize a permanently closed switch—mechanically and electronically.

Mechanical Realization of a Permanently Closed Switch After Temporarily Depressing the Switch

The top and bottom electrodes 61, 62 will be in contact once the force applied on the switch 12 of the switch film 10 is higher than a pre-determined value. Preferably, this force is approximately equal to the force needed to rupture the flexible film substrate 11 of the switch film 10. The permanently-on state of the switch 12 can be realized by using a deformable plastic material as a dielectric layer 63. When sufficient force has been applied onto the electrodes 61, 62 of the switch 12, the dielectric material 63 therein will flow outwards such that the top and bottom electrodes 61, 62 will be in contact. Deformation of the plastic dielectric material 63 will be largely retained even after the force has been released, i.e., after the pill has been extracted, thereby keeping the top and bottom electrodes 61, 62 in contact permanently. Alternatively, one or both electrodes 61, 62 can be coated with a conductive adhesive to facilitate retention of the contact, as described above.

Electronic Realization of a Permanently Closed Switch after Temporarily Depressing the Wwitch

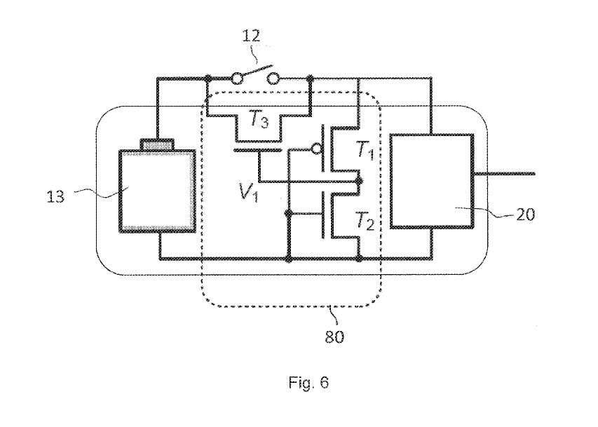

In this case, the top and bottom electrodes 61, 62 of a normally-open switch 12 are configured to be in contact only when the force applied. When the force is released, the switch will re-open—a mechanically momentarily-on switch. In this case, an electronic latch 80 as schematically depicted in FIG. 6 can be used to realize a permanent-on state of the switch 12 even after the force has been released. The electronic latch 80 comprises two transistors T1 and T2 that are energized once the switch 12 is closed upon application of a sufficient force. V1 as shown in FIG. 6 becomes the output of the battery 13 connected to the switch 12. A third transistor T3 is provided and connected in parallel with the switch 12, as shown in FIG. 6, and serves as an electronic switch that is turned on by the latch circuit 80 and remains closed or turned on until the battery 13 is exhausted. In this way, the normally-open mechanically momentarily-on switch 12 is “replaced” by the permanently switched on transistor T3 until the battery 13 is exhausted.

By providing the switch film 10 that comprises a flexible film substrate 11 having an electronic switch 12 as described in the various embodiments above, the augmented ‘smartness’ of the switch film 10 is envisaged to provide one or more of the following functions for users of an item on which the switch film 10 is provided:

(i) Transmitting information (such as to a smart phone, or any appropriate receiving device) when the switch is depressed beyond a predetermined force and/or the substrate of the film is ruptured, e.g., when removing a pill from its pocket of a pharmaceutical package, via the electronic circuit in the package. That information may subsequently be transmitted to a cloud network as part of an Internet-of-Everything. An exemplary application is the management of illness by monitoring intervals and dosages of pills contained in the pharmaceutical blister package. Said monitoring could further include (ii) below.

(ii) Monitoring environmental conditions (such as temperature, humidity, etc.) of the package, including during storage and during transportation. An exemplary application is to ascertain the condition/quality of pills in their respective pharmaceutical blister packages.

(iii) Indicating the condition/quality of the packaged item upon request. An exemplary application is a pharmaceutical blister package containing pills that is, upon request, able to provide an indication of the quality of the pills, e.g. their expiry date and the monitoring mentioned in (ii) above.

Whilst there has been described in the foregoing description exemplary embodiments of the present invention, it will be understood by those skilled in the technology concerned that many variations in details of design, construction and/or operation may be made without departing from the present invention. For example, while the embodiments described above disclose a normally-open switch, it is envisaged that the switch may be normally-closed such that depressing the switch changes its state to open and triggers transmission of a signal. While it has been described above that a battery may be provided to power each electronic circuit, the switch film may be configured such that only one battery is provided to power all the electronic circuits. Although the switch film has been described in one embodiment as comprising a sensor together with a data logger, the sensor may alternatively be provided without a data logger in the switch film.

### REFERENCES

[1] “Smart Package and Monitoring System with Indicator and Method of Making Same”, US Patent No. US20130285681 A1

[2] “Blister package with electronic content monitoring system”, U.S. Pat. No. 7,113,101 B2

[3] J. Chang, X. Zhang, T. Ge and J. Zhou, “Fully Printed Electronics on Flexible Substrates: high gain amplifiers and DAC”, Organic Electronics, vol 15, pp 701-710, March 2014.

1. A switch film comprising:
a flexible film substrate;
a switch supported by the flexible film substrate, the switch having a state consisting of one of: normally-open and normally closed, the switch configured to change its state upon application of at least a predetermined force; and
an electronic circuit supported by the flexible film substrate and connected to the switch and configured to wirelessly transmit a signal upon change of state of the switch.

2. The switch film of claim 1, wherein the switch film comprises a plurality of switches supported by the flexible film substrate and the electronic circuit is configured to wirelessly transmit a distinct signal upon change of state of each of the plurality of switches.

3. The switch film of claim 1, wherein the electronic circuit is passive.

4. The switch film of claim 3, wherein the electronic circuit comprises a radio frequency transponder and the switch is provided with a unique identification circuit.

5. The switch film of claim 1, further comprising a battery provided to power the electronic circuit.

6. The switch film of claim 5, wherein the switch film comprises a plurality of switches supported by the flexible film substrate and the electronic circuit is configured to wirelessly transmit a distinct signal upon change of state of each of the plurality of switches, and wherein the switch film comprises a plurality of electronic circuits each connected with a distinct one of the plurality of switches and configured to wirelessly transmit a distinct signal upon change of state of its connected switch.

7. The switch film of claim 1, further comprising
at least one sensor configured to sense an environmental parameter; and
an indicator configured to provide an indication associated with data obtained by the at least one sensor upon change of state of the switch.

8. The switch film of claim 7, further comprising a data logger configured to log data obtained from the at least one sensor.

9. The switch film of claim 7, wherein the electronic circuit is configured to transmit a signal comprising at least an indication of the data obtained by the at least one sensor upon change of state of the switch.

10. The switch film of claim 1, wherein the switch is a mechanically normally-open switch and the electronic circuit includes a transistor connected in parallel with the switch and a latch circuit configured to turn the transistor on when the switch is closed.

11. The switch film of claim 1, wherein the switch is a normally open switch comprising a top electrode and a bottom electrode configured to come into contact with each other upon application of the at least a predetermined force.

12. The switch film of claim 11, wherein a permanent contact is formed between the top electrode and the bottom electrode upon application of the at least a predetermined force.

13. The switch film of claim 1, wherein application of the at least a predetermined force ruptures the flexible film substrate.

14. A pharmaceutical blister package comprising:
a plurality of pockets integrally formed from a plastic sheet; each of the plurality of pockets containing therein a pill,
a sheet of aluminium foil sealing each pill in each pocket; and
the switch film according to claim 2, wherein the flexible film substrate is disposed over the sheet of aluminium foil outside the plurality of pockets and each of the plurality of switches is disposed at each of the plurality of pockets respectively.

15. The pharmaceutical blister package of claim 14, wherein each of the plurality of switches is configured to change its state upon application of the at least a predetermined force during removal of a pill from its respective pocket.

16. The pharmaceutical blister package of claim 15, wherein the signal includes date and time of removal of the respective pill from the blister package.

17. The pharmaceutical blister package of claim 14, wherein the switch film is the switch film according to claim 7, and wherein the data obtained by the at least one sensor is indicative of a condition of at least one pill in the pharmaceutical blister package.
